(19) United States
(12) Patent Application Publication
(10) Pub. No.: US 2023/0021415 A1
(43) Pub. Date: Jan. 26, 2023

(54) Manufacturing Method for Semiconductor Device

(71) Applicant: Nippon Telegraph and Telephone Corporation, Tokyo (JP)

(72) Inventors: Takuro Fujii, Tokyo (JP); Takuma Tsurugaya, Tokyo (JP); Tomonari Sato, Tokyo (JP); Shinji Matsuo, Tokyo (JP)

(21) Appl. No.: 17/787,808

(22) PCT Filed: Jan. 17, 2020
(86) PCT No.: PCT/JP2020/001469

§ 371 Date: Jun. 21, 2022

(51) Int. Cl. H01S 5/227; H01S 5/22

(52) U.S. Cl. CPC H01S 5/2272; H01S 5/2275; H01S 5/2223

(57) ABSTRACT

A first burying layer burying a side of a first ridge structure is formed by selective growth using a first selective growth mask and a third selective growth mask. The first burying layer is formed by regrowth from a surface of a second semiconductor layer on a side of the first ridge structure. At the same time, by selective growth using a second selective growth mask and a fourth selective growth mask, a second burying layer burying a side of a second ridge structure is formed. The second burying layer is formed by regrowth from a surface of a fourth semiconductor layer on a side of the second ridge structure.

### CROSS-REFERENCE TO RELATED APPLICATIONS

This patent application is a national phase filing under section 371 of PCT application no. PCT/JP2020/001469, filed on Jan. 17, 2020, which application is hereby incorporated herein by reference in its entirety.

### TECHNICAL FIELD

The present invention relates to manufacturing methods for semiconductor devices such as semiconductor lasers.

### BACKGROUND

With an exponential increase in communication volume, wavelength division multiplexing (WDM) technology having been used in relatively long-range communications is also required to be used in near-field communications in facilities such as data centers. In near field communications, because the number of optical transmission/reception devices required is significantly large, the cost of each transmission/reception device needs to be reduced. The power consumption also needs to be reduced as much as possible. Accordingly, it is necessary to fabricate compact and low-power transmission/reception devices at low costs.

In order to meet the demand for miniaturization and low power consumption, it is desirable to use optical integrated circuits each fabricated by a batch process of devices having various functions rather than integration of individual devices. In the fabrication of the optical integrated circuits, the silicon photonics technology is widely used in which thin-line optical waveguides, passive devices, and the like are fabricated by fine processing of silicon (Si). Silicon photonics applications are advantageous, for example, in that the material itself is inexpensive and that fine processing techniques having been developed in the field of electronics technology may be used. On the other hand, because silicon is an indirect transition material, a light emitting device with high efficiency has not been achieved yet. Because of this, a heterogeneous material integration of silicon and a direct transition material capable of achieving a highly efficient light emission is needed.

As heterogeneous material integration devices that satisfy the aforementioned demand for miniaturization, low power consumption, and low costs, optical devices have been developed in which a buried heterostructure is formed within a stacked structure where a plurality of thin semiconductor layers are stacked (see Non Patent Literature (NPL) 1, NPL 2, NPL 3, NPL 4, and NPL 5). The buried heterostructure refers to a structure in which a semiconductor (active layer) having a high refractive index and a small band gap is sandwiched in the vertical and horizontal directions by semiconductors having a relatively low refractive index and a large band gap. This structure makes it possible to improve an optical confinement factor of an active layer that contributes largely to various kinds of performance of a semiconductor device.

The above-discussed device having a buried heterostructure within a thin-film structure is characterized in that it typically includes a semiconductor multilayer structure with a thickness of approximately 250 nm to 500 nm and that reducing the volume of the semiconductor active layer suppresses the power consumption to a low level. A multiple quantum well (MQW) structure having excellent carrier coupling efficiency is adopted for the active layer.

In order to apply an electric field to and inject a current into the device, a lateral pin structure is adopted in which semiconductor layers on the left and right of the active layer are a p-type and an n-type. With this structure, it is possible to dispose various materials at the bottom of the active layer, and fabricate an optical integrated circuit by integrating an optical waveguide, a modulator, an array optical waveguide grating (AWG), an optical switch, an optical receiver, and the like, which are fabricated by the silicon photonics technology.

### CITATION LIST

### Non Patent Literature

NPL 1: S. Matsuo et al., “Directly modulated buried heterostructure DFB laser on SiO2/Si substrate fabricated by regrowth of InP using bonded active layer”, Optics Express, vol. 22, no. 10, pp. 12139-12147, 2014.

NPL 2: T. Okamoto et al., “Optically Pumped Membrane BH-DFB Lasers for Low-Threshold and Single-Mode Operation”, IEEE Journal of Selected Topics in Quantum Electronics, vol. 9, no. 5, pp. 1361-1366, 2003.

NPL 3: S. Matsuo et al., “Room-temperature continuous-wave operation of lateral current injection wavelength-scale embedded active-region photonic-crystal laser”, Optics Express, vol. 20, no. 4, pp. 3773-3780, 2012.

NPL 4: S. Matsuo et al., “High-speed ultracompact buried heterostructure photonic-crystal laser with 13 fj of energy consumed per bit transmitted”, Nature Photonics, vol. 4, pp. 648-654, 2010.

NPL 5: K. Hasebe et al., “High-Speed Modulation of Lateral p-i-n Diode Structure Electro-Absorption Modulator Integrated With DFB Laser”, Journal of Lightwave Technology, vol. 33, no. 6, pp. 1235-1240, 2015.

NPL 6: K. Kudo et al., “Densely Arrayed Eight-Wavelength Semiconductor Lasers Fabricated by Microarray Selective Epitaxy”, IEEE Journal of Selected Topics in Quantum Electronics, vol. 5, no. 3, pp. 428-434, 1999.

NPL 7: T. Sasaki et al., “Selective metalorganic vapor phase epitaxial growth of InGaAsP/InP layers with bandgap energy control in InGaAs/InGaAsP multiple-quantum well structures”, Journal of Crystal Growth, vol. 132, pp. 435-443, 1993.

### SUMMARY

### Technical Problem

In order to implement the WDM technology by the optical integrated circuit as described above, a plurality of laser elements each emitting light with a different wavelength need to be fabricated on the same substrate, and it is necessary to precisely control the wavelength interval between the laser elements and the oscillation wavelength of each laser element. For example, in a case in which the communication standard of “400GBASE-FR4” (CWDM) is satisfied, the oscillation wavelength required of a laser element on the short wave side differs from that required of a laser element on the long wave side by 60 nm.

The required precision of the absolute value of the oscillation wavelength of each of the laser elements is ±6.5 nm. In the case of “400GBASE-FR8/LR8” (LAN-WDM), the required oscillation wavelength range is mitigated to 36 nm, but the required precision of the oscillation wavelength is strictly made to be ±1.0 nm. It is also required to operate at high efficiency and high speed in the whole wide wavelength region.

For precise oscillation wavelength control, a distribution feedback type (DFB) laser is typically used. In the DFB laser, a diffraction grating structure is formed in the vicinity of the active layer, and the laser oscillates in any single mode determined by the lattice spacing and the equivalent refractive index of the diffraction grating. In the buried heterostructure where the semiconductor layer including the active layer buried therein is thinned, the equivalent refractive index largely varies according to the thickness and the layer structure shape of the semiconductor layer. Because of this, for the precise oscillation wavelength control, it is needed to control, as designed, the thickness of the semiconductor layer including the active layer buried therein, and fabricate the flattened layer structure.

On the other hand, in order to achieve a high efficiency and high speed operation in a wide wavelength region, matching between the material gain wavelength of the active layer and the oscillation wavelength is required.

The full width at half maximum of a photoluminescence spectrum at room temperature of a quantum well structure typically used as an active layer is substantially not greater than 30 to 4o meV. This corresponds, when converted to a wavelength, to a full width at half maximum of 4o to 50 nm in the 1310 nm band. Accordingly, when a plurality of direct modulation light sources with different operation wavelengths are fabricated using a single active layer material, unless the operation wavelength range is sufficiently narrower than a range of 40 to 50 nm, a light source with a small material gain at the oscillation wavelength is included. Therefore, a uniform high efficiency and high speed direct modulation operation may not be achieved at all the light sources. In the case where the operation wavelength range is much wider than the range of 40 to 50 nm, no oscillation may be obtained in nature.

When the above-discussed “400GBASE-FR4/FR8/LR8” is taken as an example, methods of obtaining a plurality of active layers having different wavelengths in a range of not less than 36 nm or 60 nm include selective growth of the active layer. An overview of the selective growth is depicted in FIG. 7. When a semiconductor layer 402 is grown by depositing a group III-V compound semiconductor on a semiconductor substrate 401 by the MOVPE technique, a group III organic metal such as trimethyl indium (TMIn) in a vapor phase state is provided toward a surface of the semiconductor substrate 401 at a high temperature under the atmosphere of a group V gas such as phosphine (PH₃).

In the growth of the semiconductor layer 402, when a selective growth mask 403 composed of SiO₂, SiN, or the like is formed beforehand on the semiconductor substrate 401, the semiconductor layer 402 is selectively formed on a portion of the semiconductor substrate 401 where the selective growth mask 403 is not formed. As is well known, elements are hardly attached to the surface of the selective growth mask 403 compared to the surface of the semiconductor substrate 401. Thus, many of group III elements 404 supplied to the vicinity of the surface of the selective growth mask 403 move over the surface of the selective growth mask 403 (surface migration) in a horizontal direction relative to the plane of the semiconductor substrate 401, and crystal grows selectively on the surface of the semiconductor substrate 401 where the selective growth mask 403 is not formed.

The probability (selective ratio) of the elements being attached to the surface of the semiconductor substrate 401 is significantly larger, that is, approximately 100 to 1000 times larger than the probability (selective ratio) of the elements being attached to the surface of the selective growth mask 403. Thus, many of the group III elements 404 supplied onto the selective growth mask 403 are not attached to the surface of the selective growth mask 403, but migrate to the surface of the semiconductor substrate 401 to be attached thereto. The length of the surface migration depends on the type of element. Using this fact, by changing the width and shape of the selective mask, it is possible to collectively grow a plurality of active layers having different thicknesses and mixed crystal compositions in the same epitaxial growth process (NPL 6 and NPL 7).

For example, as depicted in FIG. 8, a first selective growth mask 502a is formed in a first region 551 of a semiconductor substrate 501, and a second selective growth mask 502b is formed in a second region 552 thereof. The first selective growth mask 502a is different in mask width and/or inter-mask distance from the second selective growth mask 502b. The mask width of the second selective growth mask 502b is made greater than the mask width of the first selective growth mask 502a. By doing so, a semiconductor layer grows thicker at the second selective growth mask 502b having a wider mask width. Alternatively, by making the inter-mask distance of the second selective growth mask 502b shorter than the inter-mask distance of the first selective growth mask 502a, the same effect may be obtained.

As a result, in the same growth step, a second semiconductor layer 503b formed in an opening of the second selective growth mask 502b is thicker than a first semiconductor layer 503a formed in an opening of the first selective growth mask 502a. Further, an active layer formed being buried in the first semiconductor layer 503a has a different thickness from that of an active layer formed being buried in the second semiconductor layer 503b. In other words, in order to make different the oscillation wavelength in each of the configurations, the layers having different thicknesses are formed as discussed above.

The fabrication of a laser element of a buried heterostructure to be formed as discussed above will be briefly described with reference to FIGS. 9A to 9C. In a similar manner to that described above, the first semiconductor layer 503a is formed in the first region 551, and the second semiconductor layer 503b is formed in the second region 552 on the semiconductor substrate 501, as depicted in FIG. 9A.

Subsequently, the first semiconductor layer 503a and the second semiconductor layer 503b are patterned (processed) by, for example, selective etching of the buried active layers using a first mask soda and a second mask 504b respectively, and first and second mesa stripes 505a and 505b are formed as depicted in FIG. 9B.

Thereafter, first burying layers 506a and second burying layers 506b are formed by regrowth from the side portions of the first mesa stripe 505a and the second mesa stripe 505b while using the first mask 504a and the second mask 504b as the selective growth masks.

Because the heights of the first and second mesa stripes sosa and sosb are different from each other, the top surfaces may not be formed flat in all of the buried structures mentioned above. For example, in a case where the regrowth is carried out corresponding to the height of the first mesa stripe 505a, the thickness of the second burying layer 506b is insufficient for the second mesa stripe 505b, which makes it difficult to form the flat top surface. Furthermore, because an intermediate shape (cross-sectional shape) obtained during a process of forming the burying layers depends on various conditions of the crystal growth, it is considerably difficult to control the intermediate shape with good reproducibility, and therefore it is also considerably difficult to control the equivalent refractive index of the buried structure that is not flattened.

As described above, when the laser elements each having a different oscillation wavelength are fabricated collectively on the same substrate, there is a problem in that it is not easy to form the top surfaces of all of the laser elements flatly. In such a state, it is not easy to control the oscillation wavelength of each of the laser elements.

Embodiments of the present invention have been contrived to solve the problems described above, and an object thereof is to fabricate laser elements each having a different oscillation wavelength collectively on the same substrate in a state in which top surfaces of all of the laser elements are flat.

### Means for Solving the Problem

A manufacturing method for a semiconductor device according to embodiments of the present invention includes: a first step of forming a first cladding layer on a substrate; a second step of forming a first semiconductor layer on the first cladding layer; a third step of forming a first selective growth mask in which a first region on the first semiconductor layer is open, and forming a second selective growth mask in which a second region on the first semiconductor layer is open; a fourth step of stacking a second semiconductor layer, a first active layer, and a third semiconductor layer in the first region by selective growth using the first selective growth mask, and stacking a fourth semiconductor layer, a second active layer, and a fifth semiconductor layer in the second region by selective growth using the second selective growth mask; a fifth step of forming a third selective growth mask on the third semiconductor layer, and forming a fourth selective growth mask on the fifth semiconductor layer; a sixth step of processing the first active layer and the third semiconductor layer by etching using the third selective growth mask to form a first ridge structure in which the first active layer and a second cladding layer are stacked in the first region, and processing the second active layer and the third semiconductor layer by etching using the fourth selective growth mask to form a second ridge structure in which the second active layer and a third cladding layer are stacked in the second region; and a seventh step of forming a first burying layer burying a side of the first ridge structure by selective growth using the first selective growth mask and the third selective growth mask, and forming a second burying layer burying a side of the second ridge structure by selective growth using the second selective growth mask and the fourth selective growth mask, wherein at least one of a state in which a width of the first selective growth mask in an opening direction and a width of the second selective growth mask in an opening direction are different in dimension from each other or a state in which an opening area of the first selective growth mask and an opening area of the second selective growth mask are different in dimension from each other is brought about.

### Effects of Embodiments of the Invention

As described above, according to embodiments of the present invention, the width of the first selective growth mask in the opening direction and the width of the second selective growth mask in the opening direction are different in dimension from each other, and thus the laser elements each having a different oscillation wavelength may be fabricated collectively on the same substrate in a state in which the top surfaces of all of the laser elements are flat.

### BRIEF DESCRIPTION OF THE DRAWINGS

FIG. 1A is a cross-sectional view illustrating a configuration of a semiconductor device in an intermediate step for describing a manufacturing method for a semiconductor device according to a first embodiment of the present invention.

FIG. 1B is a cross-sectional view illustrating a configuration of the semiconductor device in an intermediate step for describing the manufacturing method for the semiconductor device according to the first embodiment of the present invention.

FIG. 1C is a cross-sectional view illustrating a configuration of the semiconductor device in an intermediate step for describing the manufacturing method for the semiconductor device according to the first embodiment of the present invention.

FIG. 1D is a characteristic diagram depicting a result of calculating a change in an optical confinement factor of a well layer in an MQW active layer.

FIG. 1E is a cross-sectional view illustrating a configuration of the semiconductor device in an intermediate step for describing the manufacturing method for the semiconductor device according to the first embodiment of the present invention.

FIG. 1F is a cross-sectional view illustrating a configuration of the semiconductor device in an intermediate step for describing the manufacturing method for the semiconductor device according to the first embodiment of the present invention.

FIG. 1G is a cross-sectional view illustrating a configuration of the semiconductor device in an intermediate step for describing the manufacturing method for the semiconductor device according to the first embodiment of the present invention.

FIG. 1H is a cross-sectional view illustrating a configuration of the semiconductor device in an intermediate step for describing the manufacturing method for the semiconductor device according to the first embodiment of the present invention.

FIG. 2A is a cross-sectional view illustrating a configuration of a semiconductor device in an intermediate step for describing a manufacturing method for a semiconductor device according to a second embodiment of the present invention.

FIG. 2B is a cross-sectional view illustrating a configuration of the semiconductor device in an intermediate step for describing the manufacturing method for the semiconductor device according to the second embodiment of the present invention.

FIG. 2C is a cross-sectional view illustrating a configuration of the semiconductor device in an intermediate step for describing the manufacturing method for the semiconductor device according to the second embodiment of the present invention.

FIG. 2D is a cross-sectional view illustrating a configuration of the semiconductor device in an intermediate step for describing the manufacturing method for the semiconductor device according to the second embodiment of the present invention.

FIG. 2E is a cross-sectional view illustrating a configuration of the semiconductor device in an intermediate step for describing the manufacturing method for the semiconductor device according to the second embodiment of the present invention.

FIG. 2F is a cross-sectional view illustrating a configuration of the semiconductor device in an intermediate step for describing the manufacturing method for the semiconductor device according to the second embodiment of the present invention.

FIG. 2G is a cross-sectional view illustrating a configuration of the semiconductor device in an intermediate step for describing the manufacturing method for the semiconductor device according to the second embodiment of the present invention.

FIG. 3A is a cross-sectional view illustrating a configuration of the semiconductor device in an intermediate step for describing a different manufacturing method for the semiconductor device according to the second embodiment of the present invention.

FIG. 3B is a cross-sectional view illustrating a configuration of the semiconductor device in an intermediate step for describing the different manufacturing method for the semiconductor device according to the second embodiment of the present invention.

FIG. 3C is a cross-sectional view illustrating a configuration of the semiconductor device in an intermediate step for describing the different manufacturing method for the semiconductor device according to the second embodiment of the present invention.

FIG. 3D is a cross-sectional view illustrating a configuration of the semiconductor device in an intermediate step for describing the different manufacturing method for the semiconductor device according to the second embodiment of the present invention.

FIG. 3E is a cross-sectional view illustrating a configuration of the semiconductor device in an intermediate step for describing the different manufacturing method for the semiconductor device according to the second embodiment of the present invention.

FIG. 3F is a cross-sectional view illustrating a configuration of the semiconductor device in an intermediate step for describing the different manufacturing method for the semiconductor device according to the second embodiment of the present invention.

FIG. 3G is a cross-sectional view illustrating a configuration of the semiconductor device in an intermediate step for describing the different manufacturing method for the semiconductor device according to the second embodiment of the present invention.

FIG. 3H is a cross-sectional view illustrating a configuration of the semiconductor device in an intermediate step for describing the different manufacturing method for the semiconductor device according to the second embodiment of the present invention.

FIG. 4 is a cross-sectional view illustrating a configuration of a semiconductor device fabricated by a manufacturing method for a semiconductor device according to an embodiment of the present invention.

FIG. 5 is a perspective view illustrating a configuration of a semiconductor device fabricated by a manufacturing method for a semiconductor device according to an embodiment of the present invention.

FIG. 6 is a characteristic diagram depicting a calculation result of n_{eq} of the base mode for a shape approximated by a rib structure in which only the vicinity of an active layer is thick in a convex shape.

FIG. 7 is an illustrative diagram for schematically describing selective growth.

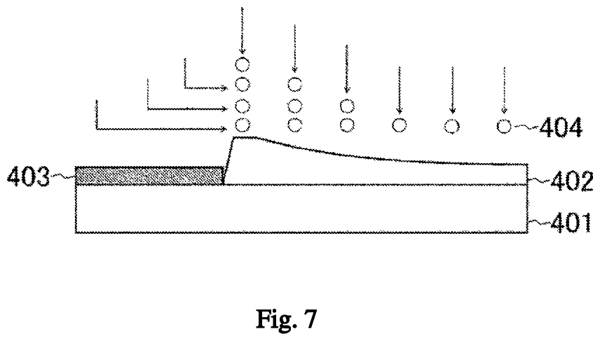

FIG. 8 is a configuration diagram illustrating a configuration of a semiconductor device of the related art.

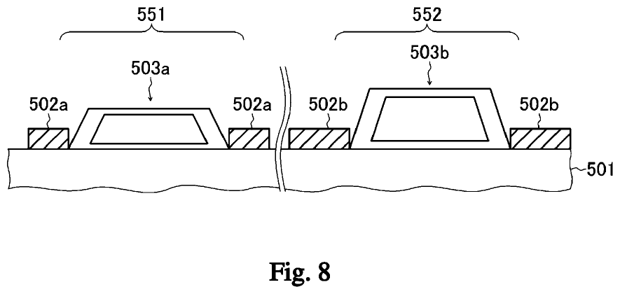

FIG. 9A is a cross-sectional view illustrating a configuration of a semiconductor device in an intermediate step for describing a manufacturing method for a semiconductor device of the related art.

FIG. 9B is a cross-sectional view illustrating a configuration of the semiconductor device in an intermediate step for describing the manufacturing method for the semiconductor device of the related art.

FIG. 9C is a cross-sectional view illustrating a configuration of the semiconductor device in an intermediate step for describing the manufacturing method for the semiconductor device of the related art.

### DETAILED DESCRIPTION OF ILLUSTRATIVE EMBODIMENTS

Hereinafter, manufacturing methods for semiconductor devices according to embodiments of the present invention will be described.

### First Embodiment

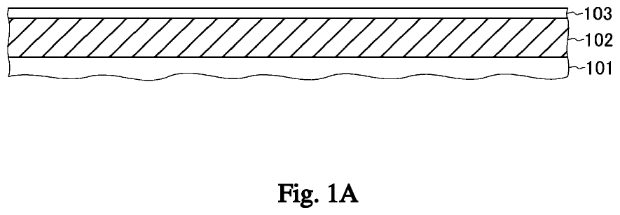

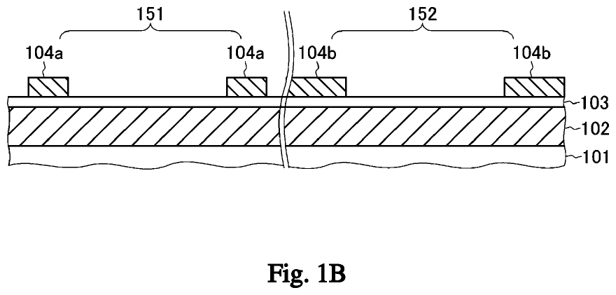

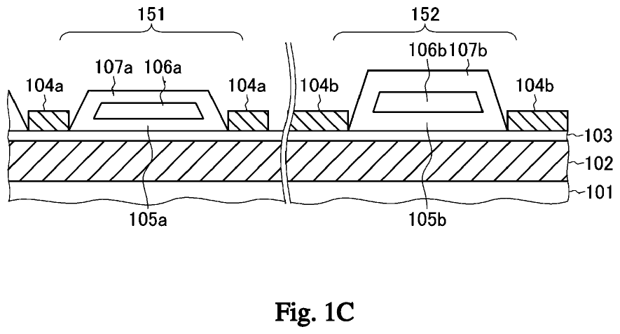

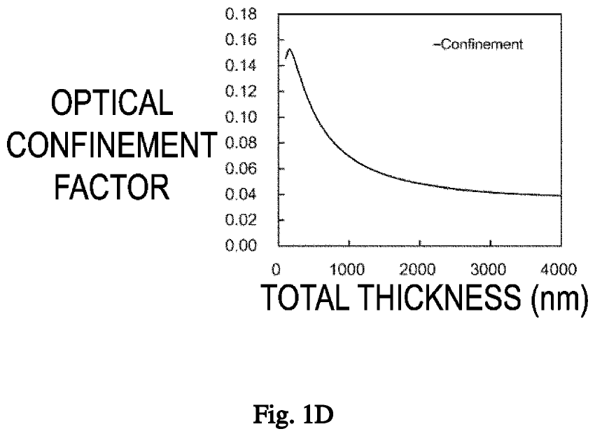

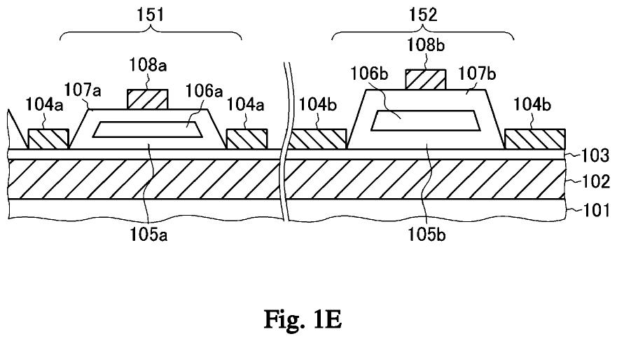

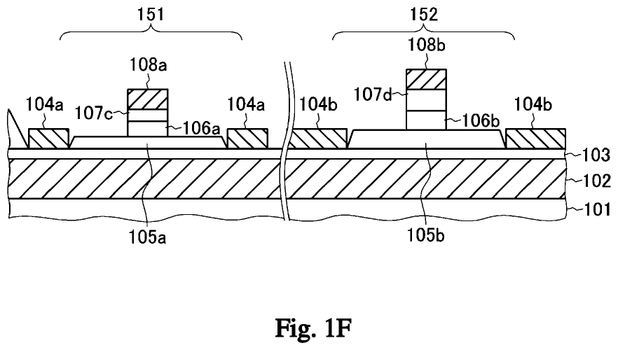

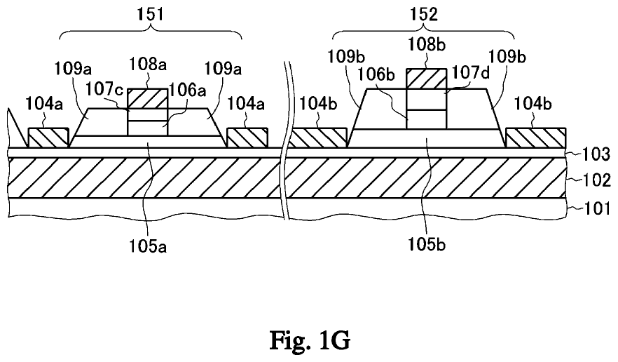

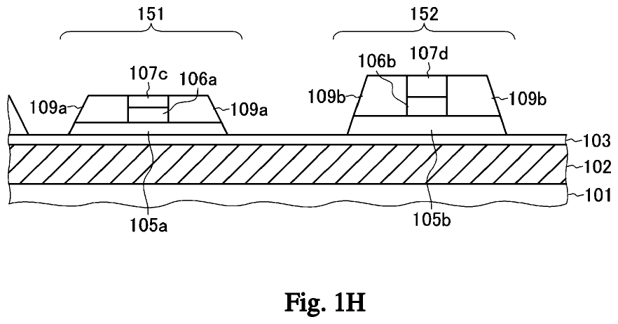

First, a manufacturing method for a semiconductor device according to a first embodiment of the present invention will be described with reference to FIGS. 1A to 1H.

As illustrated in FIG. 1A, a first cladding layer 102 is formed first on a substrate 101 (first step). The substrate 101 may be made of Si, SiO₂, Al₂O₃, InP, or GaAs, for example. The first cladding layer 102 is made of a material having a lower refractive index than that of a semiconductor layer formed on the first cladding layer 102 and being transparent with respect to an oscillation wavelength of a laser (for example, 300 nm to 1650 nm) fabricated by a method to be described below. Examples of the materials satisfying the above conditions include SiO₂, SiN, SiC, and a combination thereof.

Next, a first semiconductor layer 103 is formed on the first cladding layer 102 (second step). The first semiconductor layer 103 may be formed as follows: for example, by using a well-known wafer bonding technique, the first semiconductor layer 103 formed on an additional substrate (not illustrated) is attached to the first cladding layer 102, and then the additional substrate is removed. The first semiconductor layer 103 may also be formed by crystal growth such as metal-organic vapor phase epitaxy (MOVPE) or molecular beam epitaxy (MBE).

Next, as illustrated in FIG. 1B, a first selective growth mask 104a, in which a first region 151 on the first semiconductor layer 103 is open, is formed, and a second selective growth mask 104b, in which a second region 152 on the first semiconductor layer 103 is open, is formed (third step).

The width of the first selective growth mask 104a in an opening direction (mask width) and the width of the second selective growth mask 104b in an opening direction (mask width) are different in dimension from each other. An opening area of the first selective growth mask 104a and an opening area of the second selective growth mask 104b are different in dimension from each other. Both the mask width and the opening area of the first selective growth mask 104a can be different from those of the second selective growth mask 104b. In the example illustrated in FIG. 1B, the width of the first selective growth mask 104a in the opening direction is smaller in dimension than the width of the second selective growth mask 104b in the opening direction.

The first selective growth mask 104a and the second selective growth mask 1044b may be made of an inorganic insulating material such as SiO₂ or SiN. For example, first, SiO₂ is deposited on the first semiconductor layer 103 by sputtering or the like to form an insulating layer. Subsequently, the formed insulating layer is subjected to patterning by a known lithography technique and a known etching technique to form the first selective growth mask 104a and the second selective growth mask 104b.

Next, as illustrated in FIG. 1C, a second semiconductor layer 105a, a first active layer 106a, and a third semiconductor layer 107a are stacked in that order in the first region 151 by selective growth using the first selective growth mask 104a. At the same time, a fourth semiconductor layer 105b, a second active layer 106b, and a fifth semiconductor layer 107b are stacked in that order in the second region 152 by selective growth using the second selective growth mask 104b (fourth step).

In the selective growth, the layers described above are formed through epitaxial growth by using, for example, the MOVPE or MBE. In the selective growth, a material such as a group III element supplied to the vicinity of the top surface of each selective growth mask moves over the top surface of the selective growth mask in the horizontal direction relative to the plane of the substrate 101, and selectively attaches to the surface of the first semiconductor layer 103 exposed in the opening of the selective growth mask. Accordingly, it is sufficient that the material of the selective growth mask is a material to which elements are unlikely to attach compared to the surface of the semiconductor.

The wider the opening-direction width of the selective growth mask, and the narrower the opening of the selective growth mask, the more noticeably the crystal composition change and the growth rate acceleration caused by the selective growth are exhibited. Accordingly, by changing the width or the opening area of the selective growth masks, or by changing both of them, the thicknesses of the semiconductor layers after the selective growth may be different from each other in the same growth step. In this example, the fourth semiconductor layer 105b is formed thicker than the second semiconductor layer 105a. The second active layer 106b is formed thicker than the first active layer 106a. Furthermore, the fifth semiconductor layer 107b is formed thicker than the third semiconductor layer 107a.

The opening-direction width and the opening area of the selective growth mask are not limited, but a noticeable effect is obtained by making them approximately equal to or greater than the surface migration length of a group III element, for example, and thus they may be approximately 500 nm to 500 μm, for example.

The first active layer 106a and the second active layer 106b may have a multiple quantum well structure using a mixed crystal composed of InGaAs, InP, InGaAsP, or InGaAlAs in the case of being based on InP, for example. In the case of the quantum well structure, in addition to the wavelength change caused by the mixed crystal composition change, a light emission wavelength change of the active layer caused by the thickness change of the quantum well layer may be used. In this example, the first active layer 106a and the second active layer 106b have different thicknesses, and thus the light emission wavelengths thereof differ from each other.

By making the first active layer 106a and the second active layer 106b have the quantum well structures, it is possible to apply a significantly large strain (approximately 1.5%) to the well layer without causing any crystal defect. This makes it possible to obtain an increase in gain factor, and therefore the above-discussed configuration is suitable for a high efficiency and high speed operation of a direct modulation laser. The first active layer 106a and the second active layer 106b are not limited to the multiple quantum well structures, and may have bulk structures. In this case as well, emitted light having different wavelengths may be obtained by a change in mixed crystal composition in the first active layer 106a and the second active layer 106b of the bulk structure, in addition to the difference in thickness thereof.

By setting the total thickness of a stacked structure including the second semiconductor layer 105a, the first active layer 106a, and the third semiconductor layer 107a, and the total thickness of a stacked structure including the fourth semiconductor layer 105b, the second active layer 106b, and the fifth semiconductor layer 107b to be approximately several hundreds of nanometers, it is possible to enhance optical confinement to the first active layer 106a and the second active layer 106b.

For example, a configuration is considered in which an InP-based stacked structure including a multiple quantum well structure (MQW) active layer with a thickness of approximately 100 nm and lower and upper layers made of InP is sandwiched from below and above by layers made of a low refractive material (SiO₂). When a change in an optical confinement factor of the well layer in the MQW active layer is calculated while the total thickness is changed by changing the thicknesses of the InP layers on the upper and lower sides of the MQW active layer, the calculation result is as given in FIG. 1D. The optical confinement factor of the well layer in the MQW active layer is at its maximum when the total thickness of the InP-based stacked structure is approximately 150 nm, and it is substantially triple the optical confinement factor of a typical laser optical confinement structure with a thickness of 3000 to 4000 nm. It is understood that, as the total thickness increases, dependency of the optical confinement factor on the thickness decreases, and from the perspective of the optical confinement factor, it is effective to suppress the total thickness of the stacked structure substantially to approximately 500 nm or less.

Next, as illustrated in FIG. 1E, a third selective growth mask 108a is formed on the third semiconductor layer 107a, and a fourth selective growth mask 108b is formed on the fifth semiconductor layer 107b (fifth step). The third selective growth mask 108a and the fourth selective growth mask 108b may be made of an inorganic insulating material such as SiO₂ or SiN.

For example, first, SiN is deposited by sputtering or the like over the first semiconductor layer 103, on which the third semiconductor layer 107a, the fifth semiconductor layer 107b, the first selective growth mask 104a, and the second selective growth mask 104b are formed, thereby forming insulating layers. Subsequently, the formed insulating layers are subjected to patterning by a known lithography technique and a known etching technique to form the third selective growth mask 108a and the fourth selective growth mask 108b.

In the case where the first selective growth mask 104a and the second selective growth mask 104b have already been formed, and the third selective growth mask 108a and the fourth selective growth mask 108b include mutually different materials, a condition is used under which the first selective growth mask 104a and the second selective growth mask 104b are hardly etched by the etching processing in the patterning mentioned above.

In the case where the first selective growth mask 104a and the second selective growth mask 104b have already been formed, and the third selective growth mask 108a and the fourth selective growth mask 108b include the same material, the etching processing time in the above-mentioned patterning is controlled in such a manner as to allow the first selective growth mask 104a and the second selective growth mask 104b to remain.

After the formation of the second semiconductor layer 104a, the first active layer 106a, the third semiconductor layer 107a, the fourth semiconductor layer 105b, the second active layer 106b, and the fifth semiconductor layer 107b, the first selective growth mask 104a and the second selective growth mask 104b are removed once.

Thereafter, over the first semiconductor layer 103, on which the third semiconductor layer 107a, the fifth semiconductor layer 107b, the first selective growth mask 104a, and the second selective growth mask 104b are formed, an insulating material is deposited to form insulating layers. Subsequently, by causing the formed insulating layers to be subjected to patterning by a known lithography technique and a known etching technique, it is possible to form the third selective growth mask 108a and the fourth selective growth mask 108b as well as again form the first selective growth mask 104a and the second selective growth mask 104b.

Next, as illustrated in FIG. 1F, the first active layer 106a and the third semiconductor layer 107a are processed by etching using the third selective growth mask 108a, so that a first ridge structure in which the first active layer 106a and a second cladding layer 107c are stacked in that order is formed in the first region 151 (sixth step). At this time, a portion of the second semiconductor layer 105a on each side of the first ridge structure is exposed.

At the same time, the second active layer 106b and the third semiconductor layer 107a are processed by etching using the fourth selective growth mask 108b, so that a second ridge structure in which the second active layer 106b and a third cladding layer 107d are stacked in that order is formed in the second region 152 (sixth step). At this time, a portion of the fourth semiconductor layer 105b on each side of the second ridge structure is exposed.

The etching in the above-described step may be performed by dry etching, wet etching, or a combination thereof.

Next, as illustrated in FIG. 1G, by the selective growth using the first selective growth mask 104a and the third selective growth mask 108a, a first burying layer 109a burying each side of the first ridge structure is formed (seventh step). The first burying layer 109a is formed by regrowth from the surface of the second semiconductor layer 105a on each side of the first ridge structure.

At the same time, by the selective growth using the second selective growth mask 104b and the fourth selective growth mask 108b, a second burying layer 109b burying each side of the second ridge structure described above is formed (seventh step). The second burying layer 109b is formed by regrowth from the surface of the fourth semiconductor layer 105b on each side of the second ridge structure.

In the formation (regrowth) of the first burying layer 109a and the second burying layer 109b described above, the first selective growth mask 104a and the second selective growth mask 104b are present. As described above, the width of the first selective growth mask 104a in the opening direction is set to be smaller than the width of the second selective growth mask 104b in the opening direction. Due to this, the second burying layer 109b is formed thicker than the first burying layer 109a in the same growth step.

In other words, the first burying layer 109a is formed having the same height as that of the first ridge structure including the first active layer 106a and the second cladding layer 107c, and the second burying layer 109b may have the same height as that of the second ridge structure including the second active layer 106b and the third cladding layer 107d.

As a result, a flat state is obtained in which the top surface of the first burying layer 109a is flush with the top surface of the second cladding layer 107c. A flat state is also obtained in which the top surface of the second burying layer 109b is flush with the top surface of the third cladding layer 107d.

Thereafter, the first selective growth mask 104a, the second selective growth mask 104b, the third selective growth mask 108a, and the fourth selective growth mask 108b are removed (FIG. 1H).

In the growth using a selective growth mask, an edge of the selective growth mask of the growth layer is slightly thicker than other regions. As a result, the top surfaces of the first burying layer 109a and the second burying layer 109b using the third selective growth mask 108a and the fourth selective growth mask 108b respectively may slightly not be flat. In such a case, after removing the third selective growth mask 108a and the fourth selective growth mask 108b, the surfaces of the first and second burying layers 109a and 109b may be further flattened by making the semiconductors regrow slightly.

After each of the selective masks is removed as described above, a p-type region and an n-type region are formed in each of the first burying layer 109a and the second burying layer 109b (eighth step). An electrode to be connected to each of the p-type region and the n-type region is formed in each of the first burying layer 109a and the second burying layer 109b (ninth step). As a result, a laser element having a different oscillation wavelength is formed in each of the first region 151 and the second region 152.

According to the first embodiment described above, the top surfaces of the first burying layer 109a and the second cladding layer 107c collectively fabricated over the substrate 101, and the top surfaces of the second burying layer 109b and the third cladding layer 107d also collectively fabricated over the substrate 101 may be formed to be flat.

### Second Embodiment

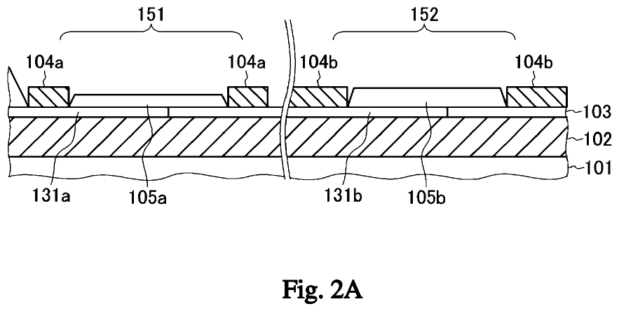

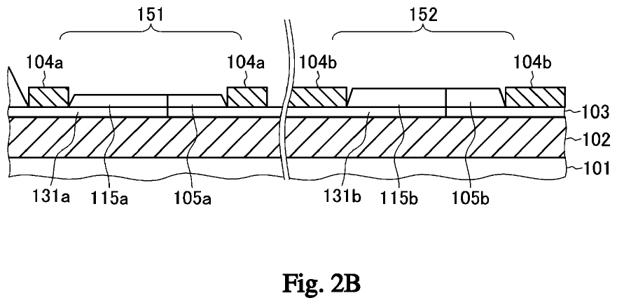

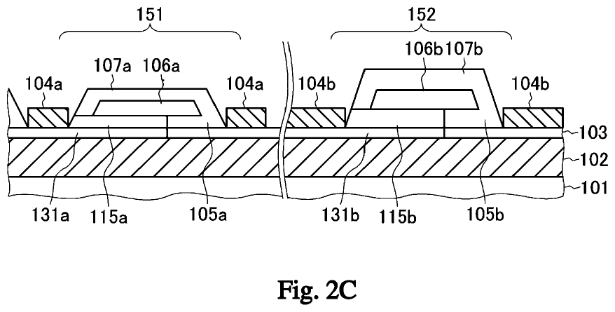

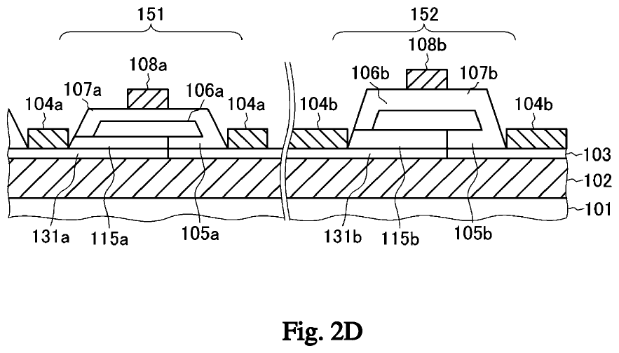

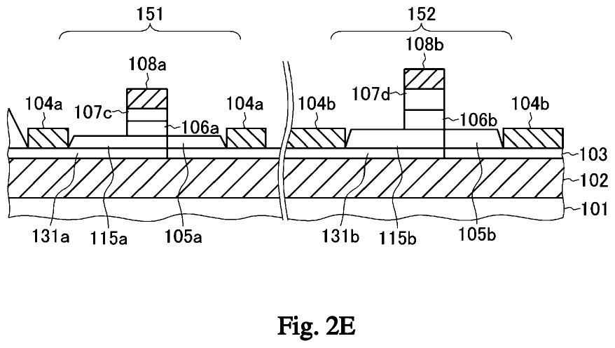

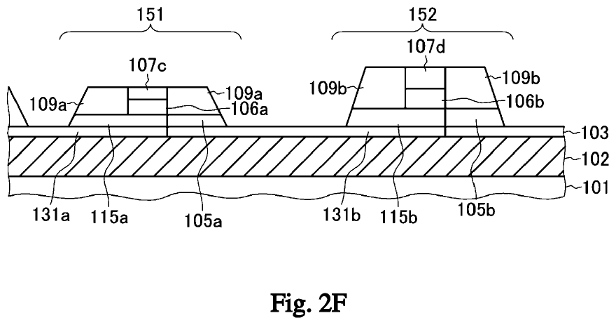

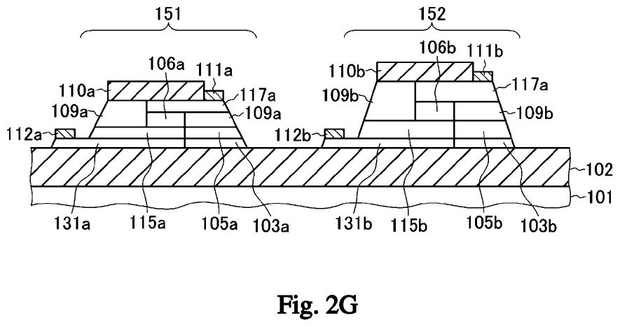

Next, a manufacturing method for a semiconductor device according to a second embodiment of the present invention will be described with reference to FIG. 1A, FIG. 1B, and FIGS. 2A to 2G.

As having been described with reference to FIG. 1A, a first cladding layer 102 is formed first on a substrate 101 (first step). Next, a first semiconductor layer 103 is formed on the first cladding layer 102 (second step). In the second embodiment, a first n-type layer 131a is formed in part of a first region 151 of the first semiconductor layer 103, and a second n-type layer 131b is formed in part of a second region 152 of the first semiconductor layer 103. The first n-type layer 131a is formed extending from one end side of the first region 151 of the first semiconductor layer 103 to a region below a first active layer 106a formed in a ridge structure to be described later. Similarly, the second n-type layer 131b is formed extending from one end side of the second region 152 of the first semiconductor layer 103 to a region below a second active layer 106b formed in a ridge structure to be described later.

Next, as having been described with reference to FIG. 1B, a first selective growth mask 104a, in which the first region 151 on the first semiconductor layer 103 is open, is formed, and a second selective growth mask 104b, in which the second region 152 on the first semiconductor layer 103 is open, is formed (third step). These configurations are similar to those of the first embodiment described before.

Next, as illustrated in FIG. 2A, a second semiconductor layer 105a is formed in the first region 151 by selective growth using the first selective growth mask 104a, and simultaneously a fourth semiconductor layer 105b is formed in the second region 152 by selective growth using the second selective growth mask 104b.

Next, as illustrated in FIG. 2B, a first n-type region 115a is formed in the second semiconductor layer 105a, and a second n-type region 115b is formed in the fourth semiconductor layer 105b, by selective injection of impurities by using a resist mask and an ion implantation technique, for example. The first n-type region 115a is formed extending from one end side of the second semiconductor layer 105a to a region below the first active layer 106a formed in a ridge structure to be described later. Similarly, the second n-type region 115b is formed extending from one end side of the fourth semiconductor layer 105b to a region below the second active layer 106b formed in a ridge structure to be described later. The first n-type layer 131a is formed in contact with a lower layer of the first n-type region 115a, and the second n-type layer 131b is formed in contact with a lower layer of the second n-type region 115b.

Subsequently, the first active layer 106a and a third semiconductor layer 107a are stacked in that order in the first region 151 by selective growth using the first selective growth mask 104a. In addition, the second active layer 106b and a fifth semiconductor layer 107b are stacked in that order by selective growth using the second selective growth mask 104b (FIG. 2C). The second semiconductor layer 105a, the first active layer 106a, and the third semiconductor layer 107a are stacked in that order in the first region 151. Meanwhile, the fourth semiconductor layer 105b, the second active layer 106b, and the fifth semiconductor layer 107b are stacked in that order in the second region 152. The materials, growth conditions, and the like of the semiconductor layers are similar to those described in the first embodiment.

Next, as illustrated in FIG. 2D, a third selective growth mask 108a is formed on the third semiconductor layer 107a, and a fourth selective growth mask 108b is formed on the fifth semiconductor layer 107b. The third selective growth mask 108a and the fourth selective growth mask 108b are the same as those of the first embodiment described above.

Next, as illustrated in FIG. 2E, the first active layer 106a and the third semiconductor layer 107a are processed by etching using the third selective growth mask 108a, so that a first ridge structure in which the first active layer 106a and a second cladding layer 107c are stacked in that order is formed in the first region 151. At this time, a portion of the second semiconductor layer 105a on each side of the first ridge structure is exposed. A bottom portion of the first active layer 106a and one side of the exposed second semiconductor layer 105a become the first n-type region 115a.

At the same time, the second active layer 106b and the third semiconductor layer 107a are processed by etching using the fourth selective growth mask 108b, so that a second ridge structure in which the second active layer 106b and a third cladding layer 107d are stacked in that order is formed in the second region 152. At this time, a portion of the fourth semiconductor layer 105b on each side of the second ridge structure is exposed. A bottom portion of the second active layer 106b and one side of the exposed fourth semiconductor layer 105b become the second n-type region 115b.

Next, as illustrated in FIG. 2F, by the selective growth using the first selective growth mask 104a and the third selective growth mask 108a, a first burying layer 109a burying each side of the first ridge structure is formed. The first burying layer 109a with an insulating structure is formed by regrowth from the surface of the second semiconductor layer 105a on each side of the first ridge structure. For example, the first burying layer 109a may include InP doped with Fe. The first burying layer 109a may have a thyristor structure in which a p-type semiconductor layer and an n-type semiconductor layer are alternately stacked.

At the same time, by the selective growth using the second selective growth mask 104b and the fourth selective growth mask 108b, a second burying layer 109b burying each side of the second ridge structure is formed. The second burying layer 109b with an insulating structure is formed by regrowth from the surface of the fourth semiconductor layer 105b on each side of the second ridge structure. For example, the second burying layer 109b may also include InP doped with Fe. The second burying layer 109b as well may have a thyristor structure in which a p-type semiconductor layer and an n-type semiconductor layer are alternately stacked.

The formation of the above-discussed burying layers is the same as that of the first embodiment described before, and a flat state is obtained in which the top surface of the first burying layer 109a is flush with the top surface of the second cladding layer 107c. A flat state is also obtained in which the top surface of the second burying layer 109b is flush with the top surface of the third cladding layer 107d.

Thereafter, the first selective growth mask 104a, the second selective growth mask 104b, the third selective growth mask 108a, and the fourth selective growth mask 108b are removed.

Next, p-type impurities are introduced into the second cladding layer 107c, part of the first burying layer 1o9a, the third cladding layer 107d, and part of the second burying layer 109b by selective injection of impurities by using a resist mask and an ion implantation technique, for example. With these impurity introduction processing operations, a first p-type region 117a is formed on the first active layer 106a, and a second p-type region 117b is formed on the second active layer 106b, as illustrated in FIG. 2G.

In the first semiconductor layer 103, a first semiconductor layer io3a of the first region 151 is isolated from a first semiconductor layer 103b of the second region 152, so that element isolation is achieved. A first p-electrode 111a connected to the first p-type region 117a is formed, and a second p-electrode 111b connected to the second p-type region 117b is formed. In addition, a first n-type electrode 112a electrically connected to the first n-type region 115a is formed in a region of the first n-type layer 131a extending from the first ridge structure. Similarly, a second n-type electrode 112b electrically connected to the second n-type region 115b is formed in a region of the second n-type layer 131b extending from the second ridge structure. A first upper cladding 110a and a second upper cladding 110b each made of an insulating material such as SiO₂ or SiN are formed on the first burying layer 109a.

As a result, a laser element having a different oscillation wavelength is formed in each of the first region 151 and the second region 152. Each of the laser elements has a so-called vertical current injection structure (vertical pin structure) in which the active layer is sandwiched from above and below by p-type and n-type regions.

In the above-described second embodiment as well, the top surface of each of the laser elements collectively fabricated on the substrate 101 may be formed to be flat.

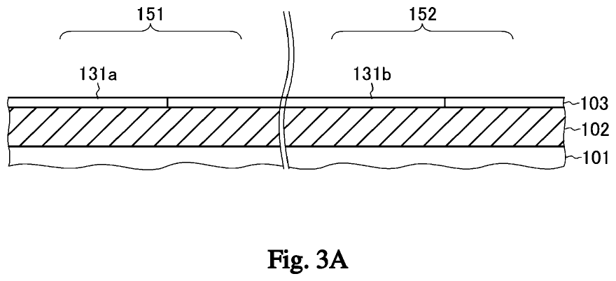

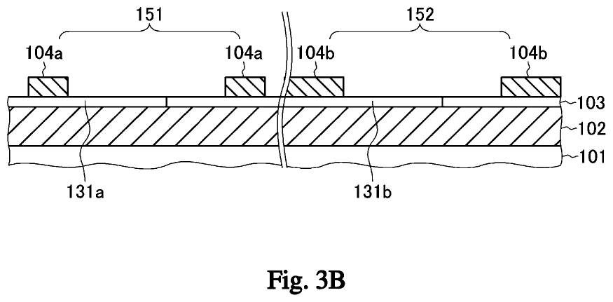

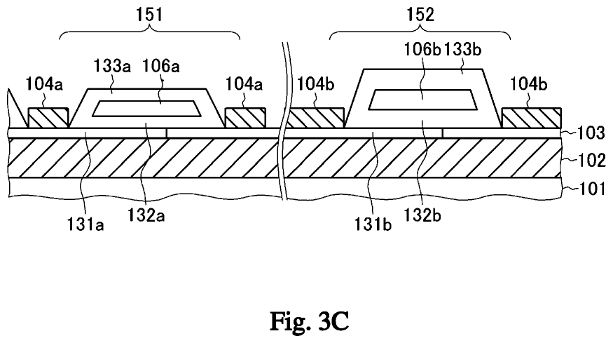

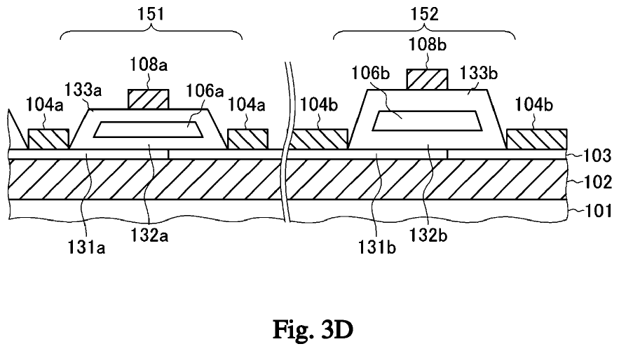

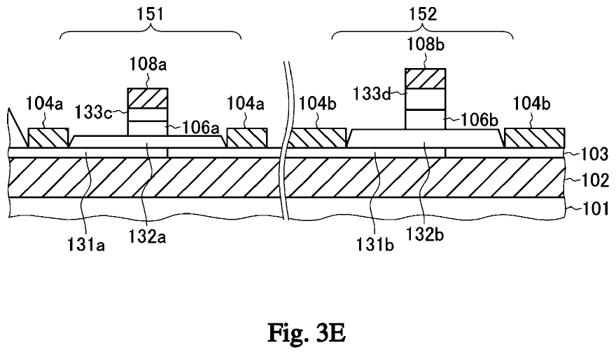

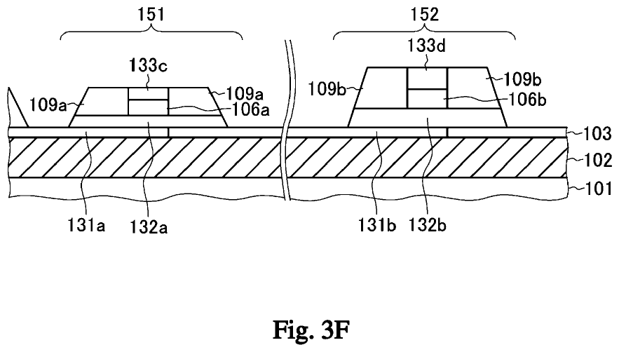

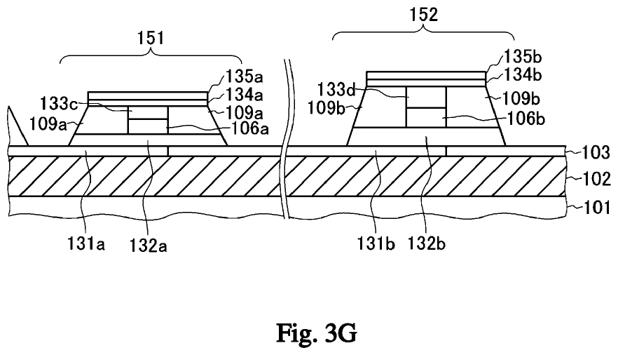

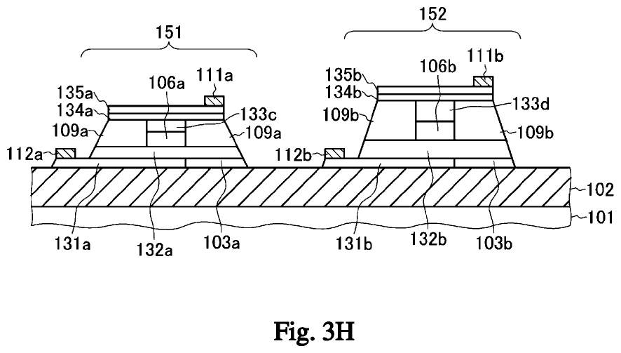

The semiconductor device described above may also be manufactured as described below. This manufacturing method will be described with reference to FIG. 1A and FIGS. 3A to 3G.

As illustrated in FIG. 1A, a first cladding layer 102 is formed first on a substrate 101 (first step). Next, a first semiconductor layer 103 is formed on the first cladding layer 102 (second step). These configurations are similar to those of the first embodiment described before.

Next, as illustrated in FIG. 3A, a first n-type layer 131a is formed in part of a first region 151 of the first semiconductor layer 103, and a second n-type layer 131b is formed in part of a second region 152 of the first semiconductor layer 103, by selective injection of impurities (for example, Si) by using a resist mask and an ion implantation technique, for example. The first n-type layer 131a is formed extending from one end side of the first region 151 of the first semiconductor layer 103 to a region below a first active layer 106a formed in a ridge structure to be described later. Similarly, the second n-type layer 131b is formed extending from one end side of the second region 152 of the first semiconductor layer 103 to a region below a second active layer 106b formed in a ridge structure to be described later.

Next, as illustrated in FIG. 3B, a first selective growth mask 104a, in which the first region 151 on the first semiconductor layer 103 is open, is formed, and a second selective growth mask 104b, in which the second region 152 on the first semiconductor layer 103 is open, is formed (third step). The formation of these selective growth masks is similar to that of the first and second embodiments described above.

Next, as illustrated in FIG. 3C, by selective growth using the first selective growth mask 104a, a second semiconductor layer 132a including an n-type semiconductor is formed in the first region 151 including an n-type semiconductor. At the same time, a fourth semiconductor layer 132b including an n-type semiconductor is formed in the second region 152 by selective growth using the second selective growth mask 104b.

Subsequently, the first active layer 106a and a third semiconductor layer 133a including a p-type semiconductor are stacked in that order in the first region 151 by selective growth using the first selective growth mask 104a. In addition, the second active layer 106b and a fifth semiconductor layer 133b including a p-type semiconductor are stacked in that order by selective growth using the second selective growth mask 104b (FIG. 3C). The second semiconductor layer 132a, the first active layer 106a, and the third semiconductor layer 133a are stacked in that order in the first region 151. Meanwhile, the fourth semiconductor layer 132b, the second active layer 106b, and the fifth semiconductor layer 133b are stacked in that order in the second region 152. The materials, growth conditions, and the like of the semiconductor layers are similar to those described in the first and second embodiments.

Next, as illustrated in FIG. 3D, a third selective growth mask 108a is formed on the third semiconductor layer 133a, and a fourth selective growth mask loft is formed on the fifth semiconductor layer 133b. The third selective growth mask 108a and the fourth selective growth mask loft are the same as those of the first and second embodiments described above.

Next, as illustrated in FIG. 3E, the first active layer 106a and the third semiconductor layer 133a are processed by etching using the third selective growth mask 108a, so that a first ridge structure in which the first active layer 106a and a second cladding layer 133c including a p-type semiconductor are stacked in that order is formed in the first region 151. At this time, a portion of the second semiconductor layer 132a on each side of the first ridge structure is exposed.

At the same time, the second active layer 106b and the third semiconductor layer 133a are processed by etching using the fourth selective growth mask 108b, so that a second ridge structure in which the second active layer 106b and a third cladding layer 133d including a p-type semiconductor are stacked in that order is formed in the second region 152. At this time, a portion of the fourth semiconductor layer 132b on each side of the second ridge structure is exposed.

Next, as illustrated in FIG. 3F, by the selective growth using the first selective growth mask 104a and the third selective growth mask 108a, a first burying layer 109a burying each side of the first ridge structure is formed. The first burying layer 109a is formed by regrowth from the surface of the second semiconductor layer 132a on each side of the first ridge structure.

At the same time, by the selective growth using the second selective growth mask 104b and the fourth selective growth mask 108b, a second burying layer 109b burying each side of the second ridge structure is formed. The second burying layer 109b is formed by regrowth from the surface of the fourth semiconductor layer 132b on each side of the second ridge structure.

The formation of the above-discussed burying layers is the same as that of the first embodiment described before, and a flat state is obtained in which the top surface of the first burying layer 109a is flush with the top surface of the second cladding layer 133c. A flat state is also obtained in which the top surface of the second burying layer 109b is flush with the top surface of the third cladding layer 133d. The first burying layer 109a and the second burying layer 109b each have an insulating structure similar to the second embodiment described above.

Thereafter, the first selective growth mask 104a, the second selective growth mask 104b, the third selective growth mask 108a, and the fourth selective growth mask 108b are removed.

Next, as illustrated in FIG. 3G, a first p-type semiconductor layer 134a including a p-type semiconductor is formed over the first active layer 106a (first burying layer 109a), and then a first contact layer 135a including a p-type semiconductor is sequentially formed. Further, a second p-type semiconductor layer 134b including a p-type semiconductor is formed over the second active layer 106b (second burying layer 109b ), and then a second contact layer 135b including a p-type semiconductor is sequentially formed. The first p-type semiconductor layer 134a and the second p-type semiconductor layer 134b may include, for example, p-type InGaAs. The first contact layer 135a and the second contact layer 135b may include highly concentrated p-type InGaAsP.

Next, as illustrated in FIG. 3H, in the first semiconductor layer 103, a first semiconductor layer 103a of the first region 151 is isolated from a first semiconductor layer 103b of the second region 152, so that element isolation is achieved. A first p-electrode 111a connected to the first contact layer 135a is formed, and a second p-electrode 111b connected to the second contact layer 135b is formed. In addition, a first n-type electrode 112a electrically connected to the first n-type region 115a is formed in a region of the first n-type layer 131a extending from the first ridge structure. Similarly, a second n-type electrode 112b electrically connected to the second n-type region 115b is formed in a region of the second n-type layer 131b extending from the second ridge structure.

As a result, a laser element having a different oscillation wavelength is also formed in each of the first region 151 and the second region 152. Each of the laser elements has a so-called vertical current injection structure (vertical pin structure) in which the active layer is sandwiched from above and below by a p-type region (p-type layer) and an n-type region.

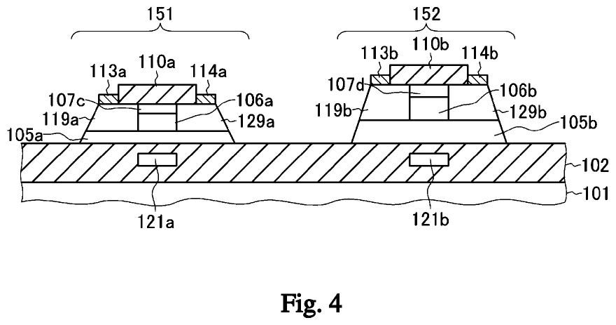

In the manufacturing method for the semiconductor device according to the embodiment, a core that is buried in the first cladding layer may also be formed at a position below each of the first ridge structure and the second ridge structure (tenth step). For example, as illustrated in FIG. 4, in the first region 151, a first core 121a made of, for example, silicon, SiN, SiOₓ, or SiOₙ is formed in the first cladding layer 102 in a region below the first active layer 106a. In the second region 152, a second core 121b made of, for example, silicon, SiN, SiOₓ, or SiOₙ is formed in the first cladding layer 102 in a region below the second active layer 106b.

The first active layer 106a is buried by being sandwiched between a first burying layer 119a of a p-type and a first burying layer 129a of an n-type. The second active layer 106b is buried by being sandwiched between a second burying layer 119b of a p-type and a second burying layer 129b of an n-type. A first p-electrode 113a is connected to the first burying layer 119a, and a first n-electrode 114a is connected to the first burying layer 129a. A second p-electrode 113b is connected to the second burying layer 119b, and, compared with a second n-electrode 114b, a resistor is connected by the second burying layer 129b. In this case, each of the laser elements has a so-called lateral current injection structure (lateral pin structure) in which the active layer is sandwiched from right and left by p-type and n-type regions.

The first core 121a and the second core 121b are disposed at positions at which optical waveguides configured by these cores are able to be optically coupled to waveguide modes by the first active layer 106a and the second active layer 106b. By doing so, the waveguide modes by the first active layer 106a and the second active layer 106b are coupled to the optical waveguides by the first core 121a and the second core 121b, and oscillation light may be taken out from the optical waveguides. The optical waveguide structure by the core as described above may be disposed above the active layer.

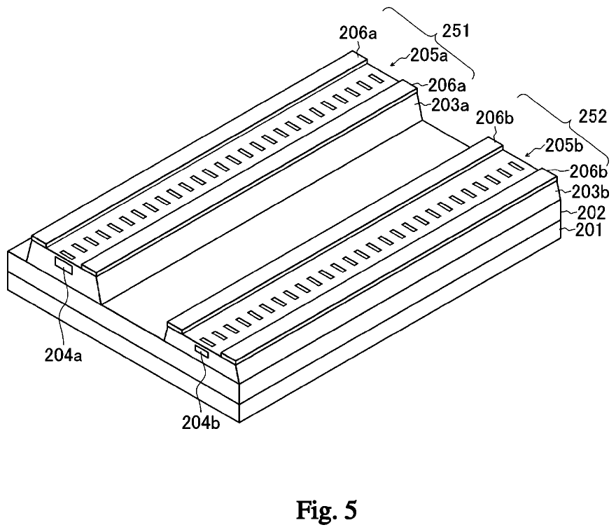

Note that the laser element described above may be a so-called distributed feedback (DFB) laser in which a diffraction grating is formed above the active layer, and a distributed Bragg reflection structure having a predetermined wavelength is provided as a resonator. For example, as illustrated in FIG. 5, a first cladding layer 202 is formed on a substrate 201, a first burying layer 203a and a first active layer 204a are formed in a first region 251, and a second burying layer 203b and a second active layer 204b are formed in a second region 252. Each of the first active layer 204a and the second active layer 204b extends in the same direction parallel to each other and configures an optical waveguide structure.

In addition, a first diffraction grating 205a extending in the same direction as the first active layer 204a is formed in the first burying layer 203a above the first active layer 204a. A second diffraction grating 205b extending in the same direction as the second active layer 204b is formed in the second burying layer 203b above the second active layer 204b. First electrodes 206a are formed on the first burying layer 203a while interposing the first diffraction grating 205a, and second electrodes 206b are formed on the second burying layer 203b while interposing the second diffraction grating 205b.

In the above-described DFB laser, when a current is injected into the active layer, oscillation is obtained at a wavelength determined by the lattice spacing of the diffraction grating and the equivalent refractive index of the buried heterostructure. As described above, because the top portion of each buried heterostructure has a flat structure, it is possible to precisely estimate each equivalent refractive index. Accordingly, by forming a diffraction grating with an appropriate lattice spacing, it is possible to precisely control the oscillation wavelength.

The diffraction grating may be formed by etching a semiconductor layer (burying layer). A layer made of a material such as SiO₂ or SiN may be formed on the burying layer, and the diffraction grating may be formed in this layer. As illustrated in FIG. 5, the diffraction grating may be exposed to the outside. In this case, the ambient air functions as a cladding. A cladding made of SiO₂ or the like may also be disposed on the diffraction grating.

It goes without saying that the DFB structure using a diffraction grating is applicable to the vertical pin structure described with reference to FIG. 2G, and in this case as well, it is possible to obtain the effect of precisely controlling the oscillation wavelength in the same manner as described above. The length of the resonator structure by the diffraction grating is not restricted, and in the case of a typical semiconductor laser, the length thereof is substantially about 10 μm to 2 mm.

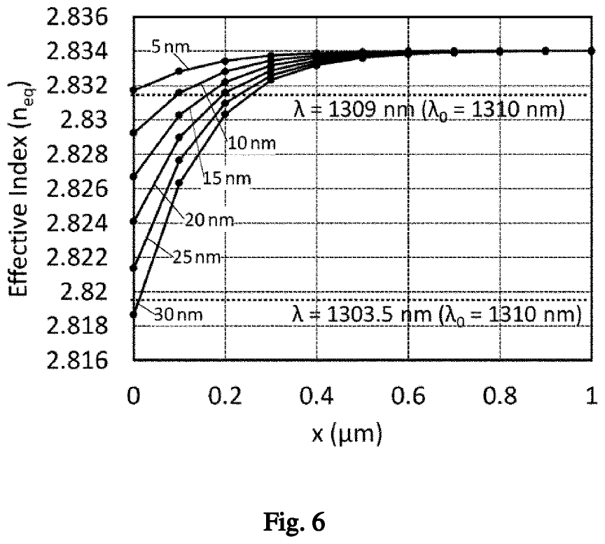

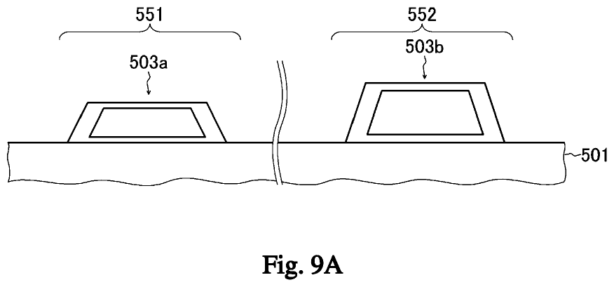

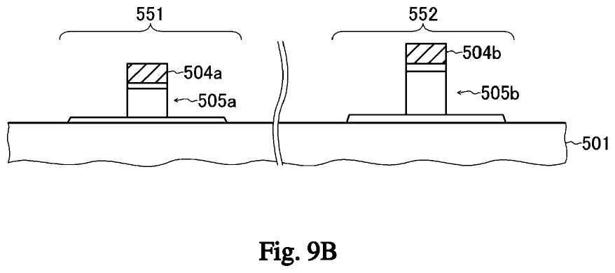

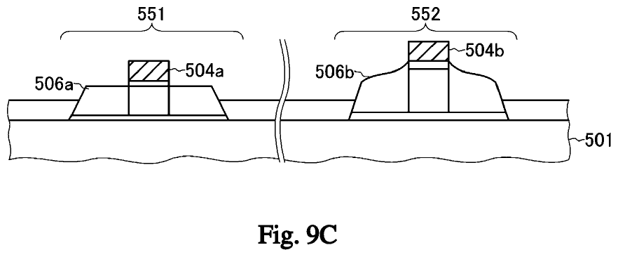

Hereinafter, wavelength controllability obtained by using embodiments of the present invention will be described. An oscillation wavelength of a DFB laser is represented by the equation “λ=2n_{eq}d”. In this equation, X is an oscillation wavelength, n_{eq} is an equivalent refractive index, and d is a diffraction grating period. From the above equation, it is understood that the oscillation wavelength is proportional to the equivalent refractive index. When a plurality of DFB laser elements each having a different oscillation wavelength are collectively fabricated by the aforementioned selective growth without use of embodiments of the present invention, a portion where the top surface is not flat is generated in the cross-sectional structure, as having been described with reference to FIG. 9C. FIG. 6 depicts a result obtained by approximating this state by a rib structure in which only the vicinity of the active layer is thick in a convex shape and calculating n_{eq} of the base mode.

The thickness of the active layer is 0.15 μm and the width in a cross-sectional view of the active layer is 0.6 μm in the calculation result depicted in FIG. 6. The total thickness of the burying layer in which the active layer is buried is 0.25 μm. The thickness of a portion above the active layer in the burying layer is 0.05 μm. The refractive index of the active layer is 3.40, the refractive index of the burying layer (InP) is 3.17, and the refractive index of the cladding layers (SiO₂) formed while sandwiching the burying layer from above and below is 1.47.

The horizontal axis in FIG. 6 represents a distance x (μm) in the lateral direction between a convex shaped end portion in a region above the active layer in the burying layer and an end portion of the active layer. A numeral assigned to each of curved lines of the graph in FIG. 6 indicates the thickness of the convex shaped portion. In this example, the calculation is carried out for six value examples, in which the thickness of the convex shaped portion takes 5 nm, 10 nm, 15 nm, 20 nm, 25 nm, and 30 nm.

The wavelength fluctuation acceptable for the wavelength multiplexing laser is, for example, ±6 nm in the case of the above-mentioned 400GBASE-FR4, and ±1 nm in the case of 400GBASE-LR8/SR8. The oscillation wavelength is different depending on the standards, and is around 1310 nm. For example, when attention is paid to a case in which a change in thickness occurs in the convex shaped portion at an end portion of the buried active layer (x=0), it is understood that the acceptable surface flatness, in order for the oscillation wavelength precision to achieve ±6 nm and ±1 nm, is not greater than about 25 nm and 5 nm respectively when the interface between the bottom portion cladding layer and the semiconductor layer is taken as a reference surface. It is understood that, even when the range is extended to 200 nm (x=0.2) from the end portion of the active layer, the surface of the convex shaped portion is required to have a surface flatness of not greater than approximately 15 to 20 nm in order to achieve an oscillation wavelength precision of ±1 nm.

The oscillation wavelength varies depending on other process error factors (the composition of mixed crystal constituting the active layer, the thickness of the semiconductor layer, the width of the active layer, and the like), and a margin for these factors also has to be secured, so that the actually required level of flatness becomes higher. When a plurality of DFB laser elements each having a different oscillation wavelength are collectively fabricated by selective growth, the thicknesses of all of the active layer, the semiconductor layer below the active layer, and the semiconductor layer above the active layer differ due to the selective growth. Accordingly, when an embodiment of the present invention is not used, it is difficult to achieve the required oscillation wavelength controllability.

On the other hand, the flatness of each element obtained when an embodiment of the present invention is used is considered to be substantially the same as the flatness obtained when buried growth with an appropriate thickness is performed on a single active layer, and a flatness of approximately ±5 nm is obtained in NPL 4. Accordingly, embodiments of the present invention make it possible to achieve an absolute oscillation wavelength control of ±6 nm or 1 nm as required by 400GBASE-FR4, 400GBASE-LR8/SR8, or the like.

As described thus far, according to embodiments of the present invention, because the width of the first selective growth mask in the opening direction and the width of the second selective growth mask in the opening direction are different in dimension from each other, the laser elements each having a different oscillation wavelength may be fabricated collectively on the same substrate in a state in which the top surfaces of all of the laser elements are flat.

Meanwhile, embodiments of the present invention are not limited to the embodiments described above, and it will be obvious to those skilled in the art that various modifications and combinations can be implemented within the technical idea of the present invention.

### REFERENCE SIGNS LIST

101 Substrate

102 First cladding layer

103 First semiconductor layer

104a First selective growth mask

104b Second selective growth mask

105a Second semiconductor layer

105b Fourth semiconductor layer

106a First active layer

106b Second active layer

107a Third semiconductor layer

107b Fifth semiconductor layer

107c Second cladding layer

107d Third cladding layer

108a Third selective growth mask

108b Fourth selective growth mask

109a First burying layer

109b Second burying layer

151 First region

152 Second region

1-4. (canceled)

5. A method for manufacturing a semiconductor device, the method comprising:
forming a first cladding layer on a substrate;
forming a first semiconductor layer on the first cladding layer;
forming a first selective growth mask in which a first region on the first semiconductor layer is open, the first selective growth mask having a first width in an opening direction;
forming a second selective growth mask in which a second region on the first semiconductor layer is open, the second selective growth mask having a second width in the opening direction, wherein the second width is different in dimension from the first width;
stacking a second semiconductor layer, a first active layer, and a third semiconductor layer in the first region by selective growth using the first selective growth mask;
stacking a fourth semiconductor layer, a second active layer, and a fifth semiconductor layer in the second region by selective growth using the second selective growth mask;
forming a third selective growth mask on the third semiconductor layer;
forming a fourth selective growth mask on the fifth semiconductor layer;
processing the first active layer and the third semiconductor layer by etching using the third selective growth mask to form a first ridge structure in which the first active layer and a second cladding layer are stacked in the first region;
processing the second active layer and the third semiconductor layer by etching using the fourth selective growth mask to form a second ridge structure in which the second active layer and a third cladding layer are stacked in the second region;
forming a first burying layer burying a side of the first ridge structure by selective growth using the first selective growth mask and the third selective growth mask; and
forming a second burying layer burying a side of the second ridge structure by selective growth using the second selective growth mask and the fourth selective growth mask.

6. The method according to claim 5, wherein:
during processing the first active layer and the third semiconductor layer by etching and during processing the second active layer and the third semiconductor layer by etching, the second semiconductor layer on the side of the first ridge structure and the fourth semiconductor layer on the side of the second ridge structure are exposed; and
in forming the first burying layer and in forming the second burying layer, regrowth is performed from a surface of the second semiconductor layer on the side of the first ridge structure and a surface of the fourth semiconductor layer on the side of the second ridge structure.

7. The method according to claim 5, further comprising:
forming a p-type region and an n-type region in each of the first burying layer and the second burying layer; and
forming an electrode connected to each of the p-type region and the n-type region in each of the first burying layer and the second burying layer.

8. The method according to claim 7, further comprising forming a core buried in the first cladding layer at a position below each of the first ridge structure and the second ridge structure.

9. The method according to claim 5, wherein forming the first burying layer and forming the second burying layer are performed simultaneously.

10. A method for manufacturing a semiconductor device, the method comprising:
forming a first cladding layer on a substrate;
forming a first semiconductor layer on the first cladding layer;
forming a first selective growth mask having a first opening area to expose a first region on the first semiconductor layer;
forming a second selective growth mask having a second opening area to expose a second region on the first semiconductor layer, wherein the second opening area is different in dimension from the first opening area;
stacking a second semiconductor layer, a first active layer, and a third semiconductor layer in the first region by selective growth using the first selective growth mask;
stacking a fourth semiconductor layer, a second active layer, and a fifth semiconductor layer in the second region by selective growth using the second selective growth mask;
forming a third selective growth mask on the third semiconductor layer;
forming a fourth selective growth mask on the fifth semiconductor layer;
processing the first active layer and the third semiconductor layer by etching using the third selective growth mask to form a first ridge structure in which the first active layer and a second cladding layer are stacked in the first region;
processing the second active layer and the third semiconductor layer by etching using the fourth selective growth mask to form a second ridge structure in which the second active layer and a third cladding layer are stacked in the second region;
forming a first burying layer burying a side of the first ridge structure by selective growth using the first selective growth mask and the third selective growth mask; and
forming a second burying layer burying a side of the second ridge structure by selective growth using the second selective growth mask and the fourth selective growth mask.

11. The method according to claim 10, wherein:
during processing the first active layer and the third semiconductor layer by etching and during processing the second active layer and the third semiconductor layer by etching, the second semiconductor layer on the side of the first ridge structure and the fourth semiconductor layer on the side of the second ridge structure are exposed; and
in forming the first burying layer and in forming the second burying layer, regrowth is performed from a surface of the second semiconductor layer on the side of the first ridge structure and a surface of the fourth semiconductor layer on the side of the second ridge structure.

12. The method according to claim 10, further comprising:
forming a p-type region and an n-type region in each of the first burying layer and the second burying layer; and
forming an electrode connected to each of the p-type region and the n-type region in each of the first burying layer and the second burying layer.

13. The method according to claim 12, further comprising forming a core buried in the first cladding layer at a position below each of the first ridge structure and the second ridge structure.

14. The method according to claim 10, wherein forming the first burying layer and forming the second burying layer are performed simultaneously.

15. The method according to claim 10 wherein the first selective growth mask has a first width in an opening direction and the second selective growth mask has a second width in the opening direction, the first width and the second width having different dimensions.
